(19) United States
(12) Patent Application Publication
(10) Pub. No.: US 2017/0040473 A1
(43) Pub. Date: Feb. 9, 2017

(54) Nanostructured Hybrid-Ferrite Photoferroelectric Device

(71) Applicant: Northeastern University, Boston, MA (US)

(72) Inventors: Yajie CHEN, Brighton, MA (US); Vincent HARRIS, Sharon, MA (US)

(73) Assignee: Northeastern University, Boston, MA (US)

(21) Appl. No.: 15/304,215

(22) PCT Filed: Apr. 14, 2015
(86) PCT No.: PCT/US2015/025764

§ 371 Date: Oct. 14, 2016

Related U.S. Application Data
(60) Provisional application No. 61/979,257, filed on Apr. 14, 2014.

(51) Int. Cl. H01L 31/032; H01L 31/072; H01L 31/18; H01L 31/0224; H01L 31/0352

(52) U.S. Cl. CPC H01L 31/032; H01L 31/022433; H01L 31/035218; H01L 31/18; H01L 31/072

(57) ABSTRACT

A photovoltaic device is fabricated using nanostructured hybrid ferrite materials with interdigital electrodes. The device includes ferrimagnetic ferrite nanopartides having a tunable narrow bandgap of 2.5 eV or less, which are deposited onto a thin ferroelectric film. The device produces an ultrahigh photocurrent density of 13-15 mA/cm² when illuminated with sunlight of 100 mW/cm², which is comparable to that of organic or silicon-based solar cells.

### CROSS REFERENCE TO RELATED APPLICATIONS

This application claims the priority of U.S. Provisional Application No. 61/979,257 filed 14 Apr. 2014 and entitled “Nanostructured Hybrid-Ferrite Photoferroelectric Devices Generating Ultrahigh Photocurrent Density”, the whole of which is hereby incorporated by reference.

### BACKGROUND

Supplying the world with energy in a sustainable manner is one of the most pressing issues of modern society. Converting the energy of sunlight into a usable form is particularly attractive since the sun provides the earth with 10,000 times more energy than present world consumption. Although the photovoltaic industry has seen a large rate of growth during the past couple of decades, the energy produced by solar cells contributes to less than 0.1% of the world's total energy consumption.

Photovoltaic effects typically involve two basic processes, including generation of electron-hole pairs as the charge carriers, and separation of electrons and holes to form the net current flow in a particular direction. Generation and separation of electrons and holes are usually achieved at an interface between two different materials. For example, in a conventional semiconductor solar cell, the electric field that exists only in the space-charge region of a p-n junction or Schottky barrier separates the charge carriers. By contrast, a ferroelectric thin film possesses an internal electric field throughout the bulk region of the film originating from its unique electrical polarization that is not completely canceled out by screening charges. Thus, photovoltaic (PV) effects are not limited to an interfacial region, and they can be generated without forming complex structures. In addition, the photo-induced voltage output in a ferroelectric thin film is not limited by an energy bandgap, as with semiconductor-based PV materials (in which the photovoltage is typically below 1V). In general, the light-to-electricity conversion efficiency of the bulk PV effect in a ferroelectric thin film is significantly lower than that of the interfacial PV effect. Up to now, ferroelectric thin-film materials have had wide energy bandgaps, so that they only absorb UV and a small fraction of visible light.

Previous experiments (K. Yao, et al., Appl. Phys. Lett. 87, 212906 (2005); W. Ji, et al., Adv. Mater. 22, 1763 (2010); M. Qin, et al., Appl. Phys. Lett., 93, 122904 (2008); M. Qin, et al., Appl. Phys. Lett. 95, 022912 (2009)) have indicated that a large portion of the photovoltage and photocurrent (approximately two thirds) is switchable in response to the ferroelectric polarization, with the direction of the photocurrent opposite to that of the polarization vector. In experimental and theoretical work on different stoichiometric thin films (lead zirconate titanate doped with lanthanum), it was found that nanoscale ferroelectric thin films could significantly improve the PV efficiency compared to thicker bulk ferroelectric films. The difference between the photovoltaic effect in a ferroelectric material and that in a conventional semiconductor p-n junction is the magnitude of the electric field that separates the photogenerated electron-hole pairs, which is approximately an order of magnitude higher than that measured in a p-n junction.

Most recently, a new mechanism of the PV effect has been discovered in bismuth ferrite (BiFeO₃ or BFO), which is different from that of conventional solar cells. (S. Y. Yang, et al., Nature Nanotechnology, 5, 143 (2010)). When bismuth ferrite is grown under controlled conditions in thin film form, it can form a multiple domain structure of differing electrical polarization arranged in alternating stripes separated by 1-2 nm domain walls, across which the electrical polarization must change direction. This provides a mechanism to increase the voltage above that of the bandgap. With contacts placed to monitor current flow parallel to domain walls, no photo-induced current was observed. But with the contacts placed to measure current flow across the domain walls, a photocurrent was observed. The voltage was shown to be a function of the number of domain walls and the spacing between them. The maximum voltage observed was over 5 times the BFO bandgap and reflected the contributions of thousands of individual domain walls. It is well known that “poling” pulses (±200V) switch the orientation of the domain polarization. When this procedure was applied to BFO films, it caused the direction of the photocurrent to reverse.

There remains a need to develop new ferrite materials for use in PV devices.

### SUMMARY OF THE INVENTION

The invention provides a ferroelectric photovoltaic nanostructured device containing hybrid ferrite materials with interdigital electrodes. The device includes ferrimagnetic ferrite nanoparticles having a tunable narrow bandgap in the range of about 2.5 eV or less, which are deposited onto a thin ferroelectric film. When illuminated with visible light, the device produces a photocurrent greater by about two orders of magnitude than that of a simple ferrite structure. Moreover, the device achieves an ultrahigh photocurrent density of 13-15 mA/cm² when illuminated with sunlight of 100 mW/cm², which is comparable to that of organic or silicon-based solar cells.

One aspect of the invention is a photoferroelectric material containing: a crystalline substrate; a first layer disposed on a surface of the substrate, the first layer containing a ferrite material possessing an internal electrical polarization; and a second layer disposed discontinuously on a surface of the first layer opposite the substrate, the second layer containing a second ferrite material.

Another aspect of the invention is a photovoltaic device containing the photoferroelectric material described above and first and second metallic contacts disposed on and in electrical contact with the second layer of the material. Even another aspect of the invention is solar array comprising a plurality of such photovoltaic devices.

Yet another aspect of the invention is a method of making the photoferroelectric material described above. The method includes the steps of: (a) providing a crystalline substrate, a first ferrite material, and a second ferrite material; (b) depositing a thin film of the first ferrite material onto a surface of the substrate to form a first layer; and (c) depositing a discontinuous thin film of the second ferrite material onto a surface of the first layer opposite the substrate to form a second layer.

Still another aspect of the invention is a method of making the photovoltaic device described above. The method includes the step of depositing first and second conductive electrodes onto a surface of the second layer of said photoferroelectric material opposite the first layer of said photoferroelectric material.

Another aspect of the invention is a method of generating electricity. The method includes illuminating the photovoltaic device or the solar array described above with sunlight.

### BRIEF DESCRIPTION OF THE DRAWINGS

FIG. 1 shows a cross-sectional schematic image of an embodiment of a photovoltaic device according to the invention.

FIG. 2A shows a scanning electron microscope (SEM) image of the surface of a CMFO film deposited on a glass slide. FIG. 2B shows an SEM micrograph of the surface of a CMFO film deposited on an Si (111) substrate.

FIGS. 3A, 3B, and 3C show SEM images of CMFO nanoparticles deposited on an Si (111) substrate. Circles in FIG. 3B indicate triangular-shaped faceting of the nanoparticles.

FIGS. 4A, 4B, and 4C show atomic force micrographs of a CMFO layer surface at different magnifications.

FIG. 5A shows an x-ray diffractogram for a CMFO thin film grown on a glass substrate. FIG. 5B shows determination of the film thickness as 33-45 nm.

FIG. 6 shows magnetization curves for CMFO films of the indicated thicknesses.

FIG. 7 shows magnetization curves for CMFO films deposited on the indicated substrates.

FIG. 8 shows an absorption spectrum of a CMFO film deposited on a glass slide. The inset shows the absorption curve as a function of photon energy.

FIG. 9 shows an x-ray diffraction result for a PV device containing an STO(100) substrate, a BFO first layer, and a CMFO second layer.

FIG. 10A shows the raw data obtained from a SQUID magnetometer for BFO thin film on an STO substrate. FIG. 10B shows the result after subtracting the diamagetism of the STO substrate.

FIG. 11 shows PV loops for a BFO thin film grown on STO (100) across Ti/Au interdigital electrodes patterned on the BFO surface.

FIG. 12 shows the details of the photomask used to prepare the interdigital electrodes for PV devices.

FIG. 13 shows a photographic image of two PV device embodiments according to the invention.

FIG. 14A shows a schematic cross-sectional representation of a control PV device having a BFO first layer deposited on an STO substrate, and a summary of the method of making the device. FIG. 14B shows a schematic cross-sectional representation of a control PV device having a CMFO second layer deposited on a BFO first layer, which in turn was deposited on an STO substrate, and a summary of the method of making the device.

FIG. 15 shows the effect of poling voltage on photocurrent for a device having a CMFO second layer deposited on a BFO first layer, which in turn was deposited on an STO substrate.

FIG. 16 shows the photocurrent as a function of illumination time for a BFO+CMFO device (upper curve) and for a BFO only device (lower curve). The inset shows the results for repeated illumination cycles (BFO+CMFO device shown as upper curve, BFO device as lower curve).

FIG. 17 shows the photovoltage as a function of illumination time for a BFO+CMFO device (lower curve) and for a BFO only device (upper curve). The inset shows the results for repeated illumination cycles (BFO+CMFO device shown as lower curve during illumination, BFO device as upper curve during illumination).

FIG. 18 shows the photocurrent dependence on illumination power (BFO+CMFO device, upper curve; BFO only device, lower curve).

FIG. 19 shows the photovoltage dependence on illumination power (BFO+CMFO device, lower curve; BFO only device, upper curve).

FIG. 20A shows a current-voltage curve for a CMFO+BFO device. FIG. 20B shows a current-voltage curve for a BFO device.

### DETAILED DESCRIPTION OF THE INVENTION

The photovoltaic (PV) device of the present invention harnesses the internal electric polarization of a ferrite thin film which is grown on a suitable crystalline substrate. Growth of ferrites on such substrates is characterized by a domain pattern that contributes to the function of the device by enhancing the photoferroelectric effect and produces voltages above the bandgap photovoltaic voltage. Electrodes disposed laterally across domain walls in the ferrite material produce high voltages and an enhanced photovoltaic effect. The ferrite material is used for its high ferroelectric polarization, and the invention further enhances the photocurrent by utilizing a discontinuous nanocrystalline layer of a narrow bandgap second ferrite material, which is different from the first ferrite material. The incorporation of the second ferrite material into or onto a thin film of the first ferrite material increases the absorption of visible wavelengths of sunlight and consequently enhances the photovoltaic effect of the resulting photoferroelectric device. The second ferrite layer is discontinuous in that the second ferrite material is distributed on a surface of the first ferrite material in patches, islands, particles, or crystals having nanoscale dimensions.

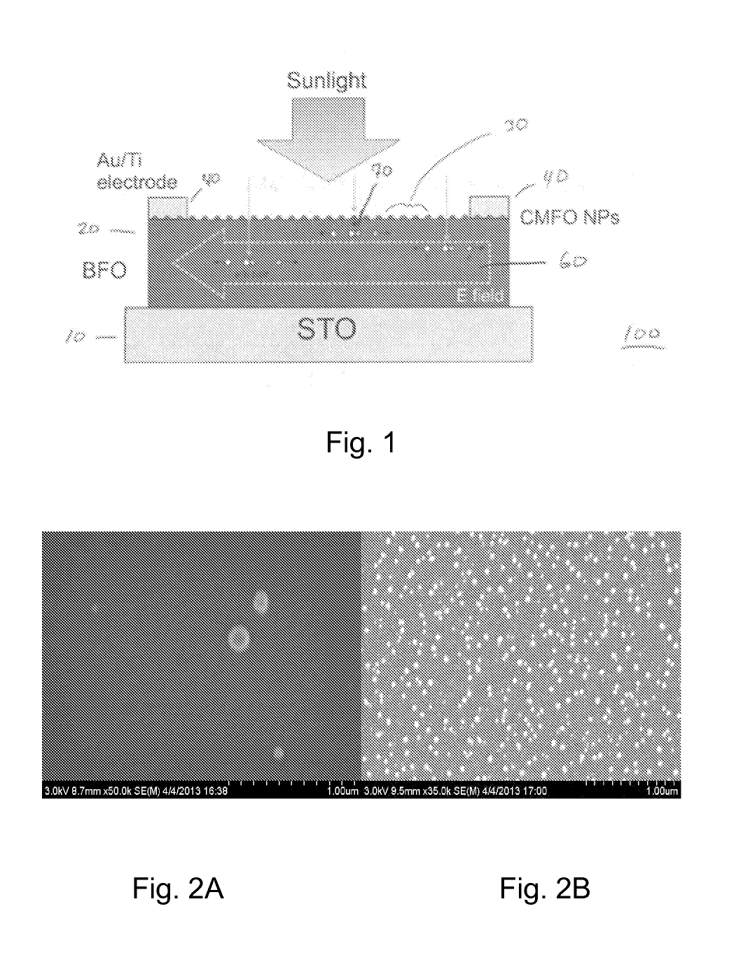

FIG. 1 shows a cross-sectional schematic representation of an embodiment of a PV device (100) according to the invention. Sunlight-induced charge excitations form electron-hole pairs (70) in both the BFO film (20, “first layer”) and the discontinuous nanocrystalline cadmium manganese ferrite (CMFO) nanoparticles (30, “second layer”), with the majority coming from the narrow bandgap CMFO. After generation, the charges migrate via BFO's internal electric field (60). The charges generated from the CMFO and BFO are then collected at the surface electrodes (40) that come directly in contact with the BFO and CMFO. An important feature of the design is the interdigital planar electrodes, which allow for light to radiate into the underlying ferrite layers and make electrical contact with both the CMFO and the BFO layers so as to capture the photocurrent.

The invention includes not only PV devices but also materials used to make PV devices. A key aspect of the invention is a photoferroelectric material containing: a crystalline substrate; a first layer disposed on a surface of the substrate, the first layer containing a ferrite material possessing an internal electrical polarization; and a second layer disposed discontinuously on a surface of the first layer opposite the substrate, the second layer containing a second ferrite material.

The substrate includes or is fabricated entirely from any material that will support growth of a thin film of ferrite material on the substrate, the thin ferrite film having an internal electrical polarization and a domain pattern that enhances the photoferroelectric effect. Preferred materials are inorganic crystalline materials that have a suitable lattice matching to ferroelectric materials that are grown as a thin film (first ferrite layer) on the substrate. Such materials include SrTiO₃ (STO), DyScO₃, MgO, and BiFeO₃ (BFO). The desired lattice matching between the substrate and first ferrite layer is characterized by a degree of mismatch that allows the first ferrite layer to possess an internal polarization as a result of distortion of its crystal lattice.

The first layer includes, or is fabricated entirely from, one or more ferroelectric materials having a spontaneous internal electric polarization resulting from electric dipoles produced by distortions of the crystal lattice. The second layer also includes, or is fabricated entirely from, one or more ferroelectric materials. It is understood that the first and second ferrite materials are not the same, i.e., they are different from each other. In certain embodiments of the invention, the first and second ferrite materials utilize different, though perhaps overlapping, portions of the solar spectrum to produce electron-hole pairs and their separation. While the first ferrite material must possess an internal electric field to separate the charge carriers after photon absorption, the second ferrite material is not required to be in such a form as to possess an internal electric field, and in some embodiments it does not.

The first and/or second ferrite materials can be, for example, an oxide such as a perovskite having the general formula ABO₃, where A and B are cations of different sizes. Alternatively, the first and/or second ferrite materials can be a spinel. Suitable examples for both the first and/or second ferrite materials include BiFeO₃, CdₓMn₍₁₋ₓ₎Fe₂O₄, [KNbO₃]₁₋ₓ[BaNi_{1/2}Nb_{1/2}O_{3-δ}]ₓ (see Nature 503, 509, 2013), (Na,K)NbO₃, LiNbO₃, KBiFe₂O₅, Pb[ZrₓTi₁₋ₓ]O₃, CoFe₂O₄ ((bandgap 1.2-1.5 eV; see APL 103, 082406 (2013), J. Appl. Phys. 113, 084101 (2013)), NiFe₂O₄ (bandgap 1.5-1.7 eV, J. Appl. Phys. 113, 084101 (2013)), NiCr_{0.8}Fe_{1.2}O₄ (bandgap 3.2 eV, AIP Conf. Proc. 1004, 112 (2008)), and combinations thereof.

An important characteristic of the first and second ferrite materials is their bandgap energy. The first and/or second ferrite materials can be, for example, a photoferroelectric material having a bandgap energy of less than about 2.5 eV, i.e., from 0 to about 2.5 eV, or in the range from about 1.0 to about 2.5 eV, from about 1.0 eV to about 2.0 eV, from about 1.0 eV to about 1.5 eV, or from about 1.3 eV to about 1.5 eV. A preferred second ferrite material is cadmium manganese ferrite (CMFO, CdₓMn₍₁₋ₓ₎Fe₂O₄), having a bandgap of 1.36-1.39 eV with x=0.3. The class of (CdMn)Fe₂O₄ materials has a bandgap of 1.1 to 2.4 eV, which varies with the stoichiometry of Cd to Mn. The use of materials having a low bandgap energy in the present invention enables PV devices of the invention to efficiently utilize the visible solar spectrum.

Additional ferrite materials having bandgap energy in the range proscribed for the invention can be identified based on simulation of bandgap energy, e.g., as described in M. Feng, X. Zou, C. Vittoria, V. G. Harris, Ab Initio study on manganese doped cadmium ferrite Cd₁₋ₓMnₓFe₂O₄, IEEE Trans. Magnetics, 47(2), 324 (2011); M. Penicaud, et al, Calculated electronic band structure and magnetic moments of ferrites, J. Magn. Magn. Mater.103 (1992), 212-220; Markus Meinert and Günter Reiss, Electronic structure and optical bandgap determination of NiFe₂O₄, 2014 J. Phys. Condens. Matter 26, 115503.

Ferroelectric materials used in the first layer of PV devices according to the invention have a periodic domain or stripe domain structure with nanometer scale domain walls, which allows them to produce photovoltages larger than the material's bandgap would otherwise support. The orientation of the bands in these materials can be controlled by the mode of growth of the film and by applied electric fields, which has been described in S. Y. Yang, et al., Above-bandgap voltages from ferroelectric photovoltaic devices, Nature Nanotechnology 5, 143 (2010). The ferroelectric domain walls of the first layer material should have built-in potential steps, arising from the component of the polarization perpendicular to the domain wall. Under that condition, the photovoltage measurement depends sensitively upon domain direction. The domain direction therefore is taken into account when configuring the PV device electrodes.

The second layer is discontinuous, so as to admit light into the first layer. The second layer preferably is configured as one or more patches, islands, or clusters of second ferrite material. The second ferrite material in the second layer can be configured in the form of nanoparticles, nanocrystals, or quantum dots, combinations thereof, and/or clusters thereof. Nanoparticles of the second ferrite material can be fabricated by a variety of known techniques. For example, nanoparticles of CMFO can be grown on BFO films, glass, or Si substrates by pulsed laser deposition using 20 minute deposition time, pulsed laser shots at 10 Hz frequency, 900° C. substrate temperature, and 1 mTorr chamber pressure with an atmosphere of 20% Ar and 80% O₂.

Both the first and second layers have thicknesses in the nanometer range (i.e., from 1 to 999 nm). For example, in certain embodiments the thickness of the first layer is in the range from about 10 nm to about 200 nm. Preferably the thickness of the first layer is small enough to substantially avoid recombination of electrons and holes during operation of the PV device. Preferably the thickness of the second layer is from about 2 nm to about 10 nm. If the second layer consists of a plurality of nanoparticles distributed as a discontinuous layer not more than one nanoparticle in thickness, then the thickness of the second layer corresponds to the diameter of the nanoparticles, which is preferably from about 2 nm to about 10 nm. Coverage of the first layer by the second layer is preferably in the range from about 20% to about 80% of the surface area of the first layer.

The substrate, first layer, and second layer as described above form an assembly of photoferroelectric material that can be used in the fabrication of a photovoltaic (PV) device. For that purpose, the photoferroelectric material is preferably planar in configuration. In order to make such a PV device, electrodes must be attached to the upper surface of the material, such that electrical contact is established with the first layer, where the two electrodes can collect the charge carriers from either end of the polarization field of the first layer, as well as from the second layer. The electrodes can be deposited by any known technique for preparing PV electrodes. The electrodes preferably have an interdigital configuration, such as a planar interdigital configuration, and contain a conductive metal, or an alloy of conductive metals, which is in contact with both the first and second layers. For example, the electrodes can be fabricated by photolithography and can include one or more conductive metals selected from gold, silver, titanium, aluminum, chromium, and copper. The PV device can be covered by a transparent cover, such as a cover made of glass or acrylic, so as to protect the photoferroelectric material and electrodes without significantly attenuating incoming solar radiation.

A PV device of the present invention is characterized as producing an ultrahigh photocurrent for the class of PV devices using ferroelectric materials up to present. Experiments have shown that the PV devices of the present invention are capable of delivering a photocurrent of at least about 13-15 mA/cm² when illuminated with sunlight of 100 mW/cm². Table 1 below lists the photocurrent produced by PV devices of the invention compared with simple single-layer devices containing BFO and other materials.

TABLE 1
Characteristics of Ferroelectric PV Devices with Different Materials

| Ferroelectric | | | | | |
|---|---|---|---|---|---|
| photovoltaic | Lamination | J_{SC} | | FF | |
| device | (mW/cm²) | (mA/cm²) | V_{OC} (V) | (%) | Reference |
| BFO | 285 | 0.11 | 6-17 | | Nat. NanoTech, 5, 143 |
| | | | | | (2010) |
| BFO | 10 | 4 × 10⁻³ to | 0.035 | | Sci,. 324, 63 (2009) |
| | | 1 × 10⁻² | | | |
| BFO | 20 | 0.2 pc | | | Nat. Comm, 4, 1990 |
| | | | | | (2013) |
| BFO | 100 | 0.04 | | | NanoTech, 24, 275201 |
| | | | | | (2013) |
| BFO | ? | 1 × 10⁻³ | 30 | | Nat. Comm, 2, 256 |
| | | | | | (2011) |
| BFO | 285 | 1-5 | | | APL 95, 062909 (2009) |
| | 100 (cal) | 0.5 | | | |
| KBNNO | | 1 × 10⁻⁴ | 7 × 10⁻⁴ | | Nature 503, 509 (2013) |
| (PbLa)(ZrTi)O₃ | | 2.5 × 10⁻⁵ | | | JAP 84, 1508 (1998) |
| (Na,K)NbO₃ | | 2.5 × 10⁻⁵ | | | J. Am. Cream. Soc. 96, |
| | | | | | 146(2013) |
| KBiFe₂O₅ | | 1.5 × 10⁻² | 9 | | Sci. Rep. 3, 1265 |
| | | | | | (2013) |
| BFO/CMFO | 100 | 15 | 0.7 | | This invention |
| | . | | | | |
| OPV* | 100 | 7-11 | 0.6 | 0.62 | Nat. Comm. 3, 1043 |
| | | | | | (2012) |
| FE/OPV* | 100 | 13.8 | 0.66 | 0.54 | Nat. Mater. 10, 296 |
| | | | | | (2011) |

*Organic-ferroelectric photovoltaic device

The PV devices of the present invention can be connected to form an array of devices, such as a typical solar panel array produced from other materials like silicon. Such arrays can be used to generate electricity by illuminating them with sunlight according to well understood practices.

### EXAMPLES

### Example 1

### Growth of Cadmium Manganese Ferrite Film

Calculation indicated a relationship between bandgap and manganese concentration for a CdₓMn₍₁₋ₓ₎Fe₂O₄ (CMFO) ferrite system. A composition of x=0.3, corresponding to a bandgap of 1.39 eV, was selected. Pulsed laser deposition (PLD) growth of CMFO was first performed using a pressed powder pellet target with a composition adjusted to compensate for the relative deposition rates of the constituent powders, so as to achieve the selected composition. The target was used to grow samples of CMFO on glass slides for optical absorption measurements. The tuning of the target powder concentrations was accomplished by making a target and performing energy-dispersive X-ray analysis (EDXA) of a deposited film from that target. The concentration values were tuned by changing the target powder composition. A series varying sample thicknesses were grown from these pressed targets on standard laboratory glass slides.

The target was made from raw oxides, matched to a desired composition of CdₓMn₍₁₋ₓ₎Fe₂O₄, with x=0.3. The oxide powders (Fe₂O₃ 99.945%, CdO 99.9%, and MnCO₃ 99.9%, see Table 2) were weighed and mixed using a ball mill for 15 minutes in forward directcion, then again in reverse, at 350 rpm in reagent grade ethanol. After mixing in the ball mill, the powders were dried on a hotplate at 80° C. The low vapor pressure for Cd resulted in some boil off at elevated temperatures during sintering. To compensate for this, an amount of CdO was used corresponding to x=0.32 (i.e., 0.02 higher than the target of x=0.3). Then, the mixture was axially pressed into a pellet 1.25″ in diameter with 6 tons of force. The pressed green body was then sintered at 750 C for 4 h in air.

TABLE 2
Powder Composition for CdₓMn₍₁₋ₓ₎Fe₂O₄,
x = 0.32 Target for Calcination

| POWDER | Wt % | Weight for 30 g Batch |
|---|---|---|
| CdO | 0.1473 | 4.419 g |
| MnCO₃ | 0.2802 | 8.406 g |
| Fe₂O₃ | 0.5725 | 17.17 g |

CMFO film was grown on a glass slide using PLD performed under the conditions described in Table 3.

TABLE 3
Deposition Conditions of CMFO Film
DEPOSITION CONDITIONS (for CMFO optical absorption studies):

Pulsed laser deposition using a KrF excimer laser at 248 nm wavelength,
an energy of 200 mJ/pulse, and a laser pulse frequency of 10 Hz
Substrate temp = 500° C.
Base Pressure = 1.5-2.5 × 10⁻⁶ Torr
Working Gas Pressure = 1 m Torr (by Baritron Vacuum Guage) [20% Ar,
80% O₂]
Deposition time was varied to achieve an array of sample thicknesses
(measured by x-ray reflectivity)

### Example 2

### Characterization of Cadmium Manganese Ferrite Films

Compositional concentrations of the thin films were determined by energy dispersive x-ray analysis (EDS or EDXS) which was performed in-situ with scanning electron microscopy (SEM). SEM images showing morphology of the films varied from sample to sample. The main factor governing these changes was the substrate which was used.

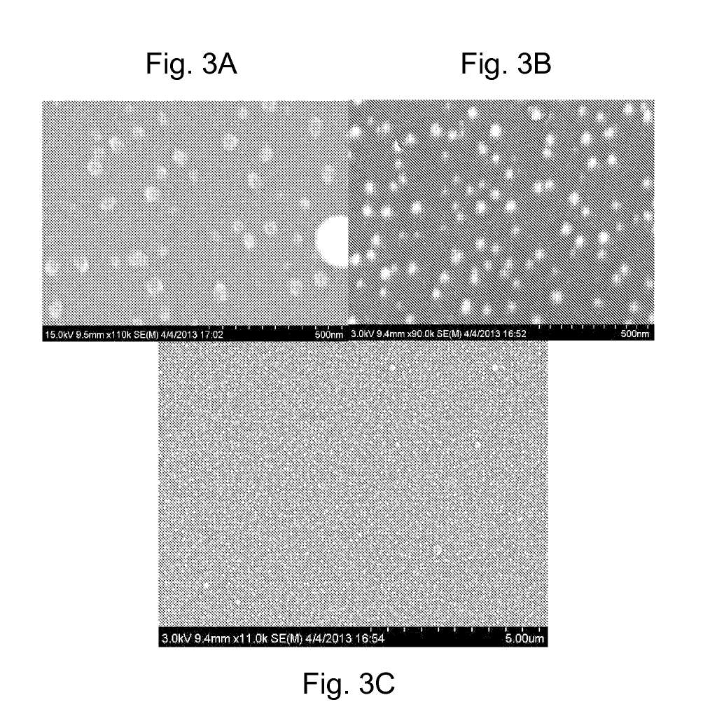

The samples grown for absorption measurements were grown on glass slides and an SEM micrograph of the surface is shown in FIG. 2A. For the most part the glass slide samples had very uniform film growth and few discrepancies in the surface. In FIGS. 2A and 2B, the samples were grown at the same time on two different substrates at 500° C. The sample grown on Si (111) (FIG. 2B) showed self-assembly of nanoparticles. The SEM images obtained from this growth are shown in FIGS. 3A-C. The nanoparticles showed a size distribution of approximately 20-50 nm in diameter. The nanoparticles possessed a highly faceted morphology, and some show a triangular geometry. This indicated a strong tendency for epitaxial alignment with the underlying Si (111) crystal geometry. It also indicated that increasing the growth temperature resulted in higher atomic mobility and an increased crystallization rate.

The faceting of the nanoparticles and their alignment with the substrate also provided insight into their formation. The nanoparticles appeared to be created by the well-known self-assembly mechanism of lattice mismatch. This mechanism involves the selection of a crystalline substrate material that has a lattice structure that differs from that of the film. This creates a strain between the two materials and stresses the epitaxial growth of the film, which causes the material to grow discontinuously by coalescing into clusters. These clusters often nucleate at specific lattice coordination sites on the substrate. The lattice mismatch between CFMO (8.526 Å) and Si (111) (7.679) is 9.9% which is more than enough for this growth mode to dominate.

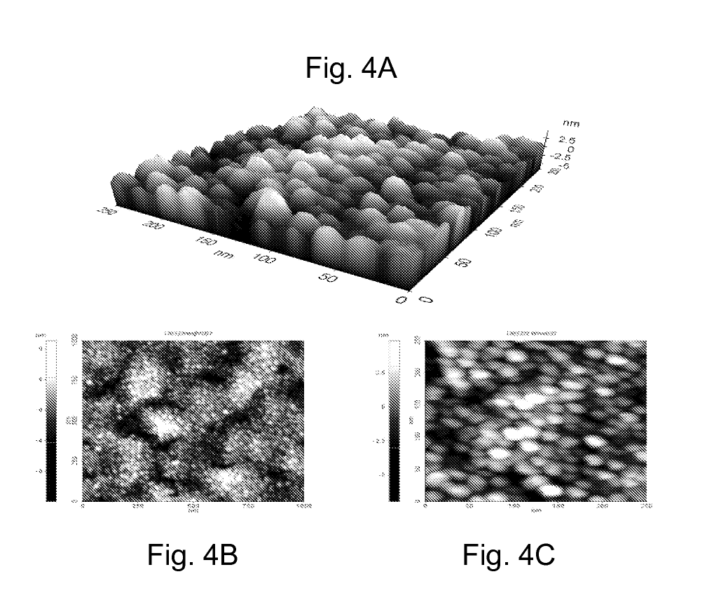

The morphology of the top CMFO layer of a full trilayered device (see Example 4) was characterized by atomic force microscopy (AFM). The device included an STO (100) substrate, upon which was grown a BFO layer, and having a top layer of CMFO deposited onto the BFO layer. The BFO layer was deposited for 45 min, and the CMFO layer was deposited for 5 minutes. FIGS. 4A-4C show atomic force micrographs of the CMFO layer surface. Using the deposition rate calculated by XRR (see below), the CMFO layer had a thickness of about 2.4 nm. The nanoparticles (or nanocrystals) shown on the surface had a feature height of 2.5-4 nm. The morphology of the CMFO film is indicative of a Volmer-Weber growth mode. Here, Volmer-Weber island growth created feature sizes that are taller than the thickness of a continuous thin film of the CMFO layer, indicating that vertical growth of Volmer-Weber islands was preferred over epitaxial nucleation and growth on the BFO underlying layer. The discontinuous layer explains how the Ti/Au electrodes of the device made contact to the underlying ferrite bilayer and also provides evidence for where the charge is traveling during device exposure to visible light. Since the layer was not a uniform film, the Ti/Au contacts are believed to make contact with the underlying BFO layer.

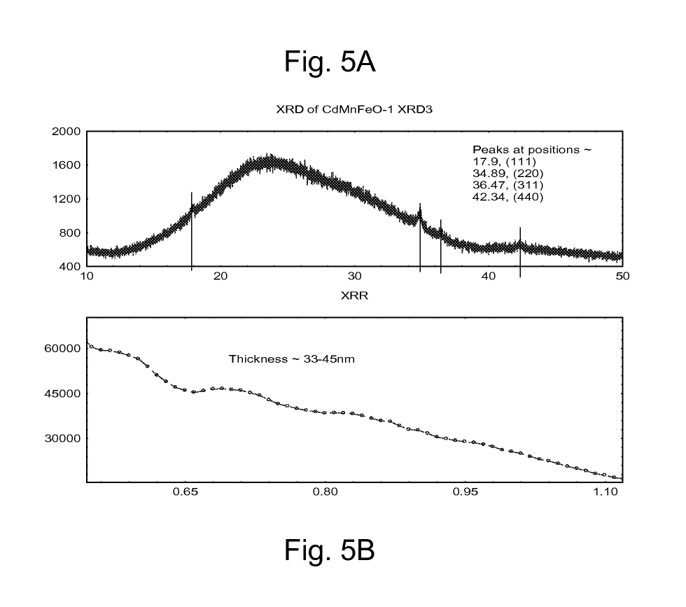

An x-ray diffractometer was used to perform x-ray reflectivity (XRR) measurements on CMFO thin films. With XRR the x-ray beam is moved to irradiate the surface at very small angles. At these angles x-rays reflect back and forth between the film-substrate interface and the top surface of the film. FIG. 5A shows an x-ray diffractogram for a CMFO thin film grown on a glass substrate. The density of the film was determined as 4.943 g/cm³. Lattice constants of CMFO ferrite were calculated to be cubic lattice constant a=b=8.573 Å, and c=8.6615 Å. The constants reveal a slight elongation along the c-axis giving a quasi-tetragonal structure. Using XRR on the sample shown above, the thickness was calculated as 33-45 nm (FIG. 5B). Using an average of the different thicknesses determined for different samples, the average deposition rate of 0.24 nm/min was obtained.

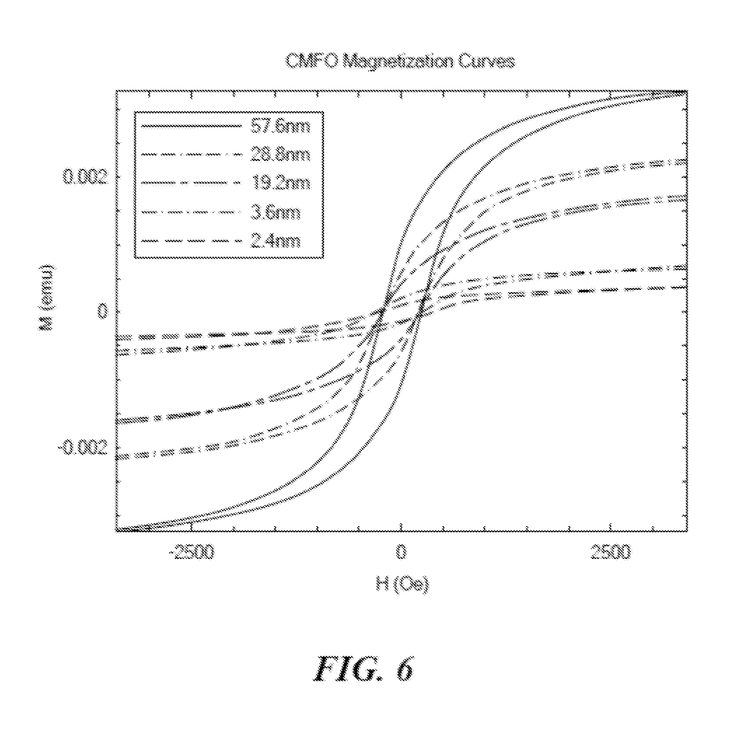

Vibrating sample magnetometer (VSM) measurements were obtained for a series of CMFO thin films of different thicknesses, and the results are shown in FIG. 6. From these it is apparent that the saturation magnetization increases with thickness and deposition time. The thicknesses of the films were calculated based on deposition rates measured by x-ray reflectivity.

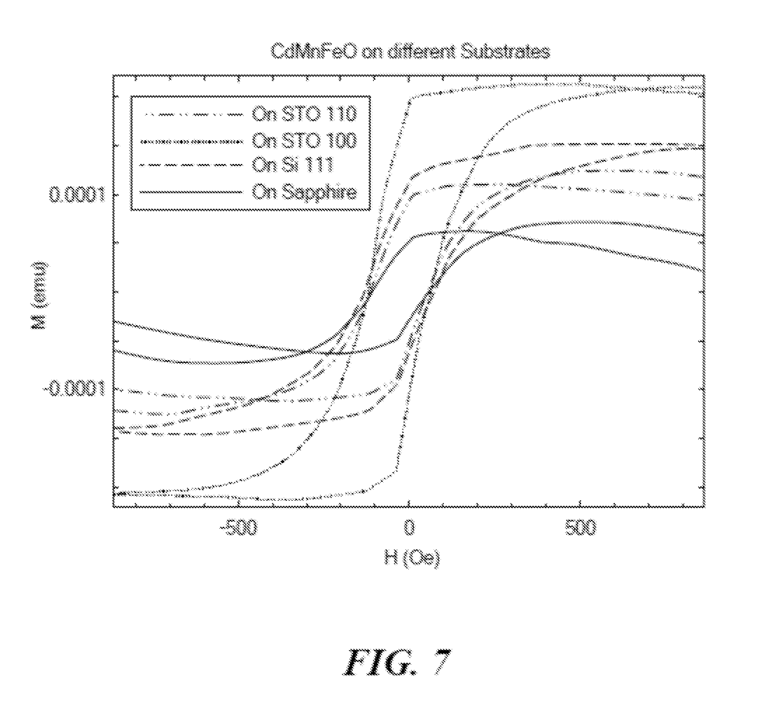

Another experiment determined the magnetization of CMFO films grown on four other substrates. PLD growth of CMFO from a sintered ferrite target was carried out for 20 min at 900° C., 1 mTorr (20% Ar and 80% O₂). On the substrate holder four different substrates were mounted: Si (111), STO (110), STO (100) and SiO₂ (0001). FIG. 7 shows the room temperature magnetization hysteresis loops from each of the samples. These loops show a higher coercivity, higher squareness, and higher saturation magnetization than for CMFO films grown on glass slides. Since these substrates can withstand higher temperatures than glass slides, the films were grown at a higher substrate temperature, (900° C. as opposed to 500° C. for glass slides). Also adding to the squareness is the crystallographic orientation of the film with the substrate, which seems to have been best oriented on the STO (001) substrate.

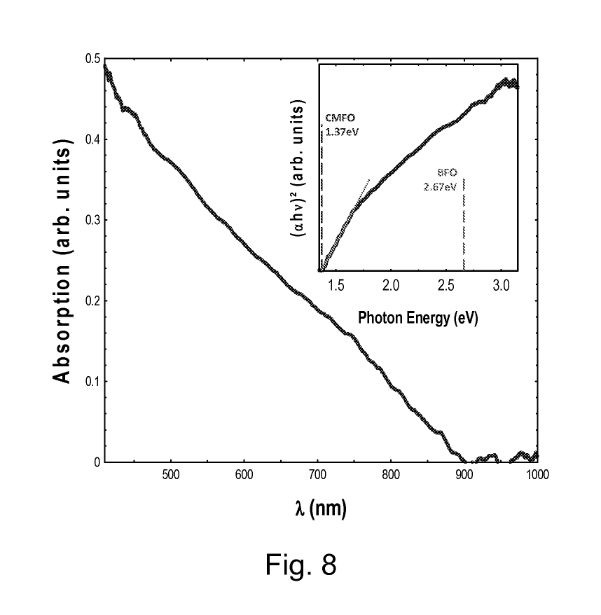

In order to determine whether CMFO has a bandgap appropriate for the solar spectrum, optical absorption measurements were performed on CMFO films grown on glass. The wavelengths of radiation that were absorbed by the film were a direct indication of the bandgap of the material. Absorption measurements were performed via relative transmission optical spectroscopy (UV-Vis). The transmission was measured with an Ocean Optics USB4000 Spectrometer coupled with a halogen lamp source. Optical fibers were used to both source and collect light within close proximity to the samples. Using the Ocean Optics software, a rigorous process was used to obtain the absorption curve for samples of CMFO grown on glass slides. The process used was to first collect a dark background with the light source turned off. Then, a reference spectrum was obtained with the sample removed from the holder and the source turned on. Next, the transmission through the sample was collected. This transmission plot was transformed into the absorption seen in FIG. 8 by dividing by the reference spectrum (both the transmission and the reference were minus the dark background). Finally, the same process was repeated to measure the spectral absorption of the glass substrate. The absorption of the sample was then plotted after subtraction of the absorption of the glass substrate in FIG. 8. The inset of FIG. 8 shows the absorption curve as a function of photon energy. From this curve the optical bandgap could be deduced via the T_{auc} method, which is used for determining the bandgap of amorphous and nanocrystalline materials. Since the CMFO thin films exhibited a large amount of localized photon scattering, a clear bandgap edge is not evident in the absorption plot. Instead the T_{auc} approximation can be used to draw a tangent from the linear region in the absorption and deduce the bandgap from its intersection with the x-axis. Use of this approximation to calculate the gap, shown in the inset of FIG. 8, resulted in a bandgap of about 1.37 eV. This number agrees closely with the 1.3962 eV gap calculated by theory for Cd₁₋ₓMnₓFe₂O₄, with x=0.25.

### Example 3

### Growth and Characterization of a Cadmium Manganese Ferrite Film on a Bismuth Ferrite Film

A BiFeO₃ (BFO) target was made by a conventional ceramic process. BFO films then were grown on SiTiO₃ (100) (STO) by PLD for 1 hr at 900° C., with a base pressure of 1.6×10⁻⁶ Torr and a 50 mTorr working gas pressure of O₂. Thickness of BFO film was estimated to be about 20 nm.

The crystalline characteristics of the BFO layer and its epitaxial relationship to the underlying STO (001) substrate were determined by x-ray diffraction (XRD) of the thin film bilayer of BFO and CMFO. The diffraction patterns were compared to previous studies on BFO thin film crystal structure when grown on STO (100).

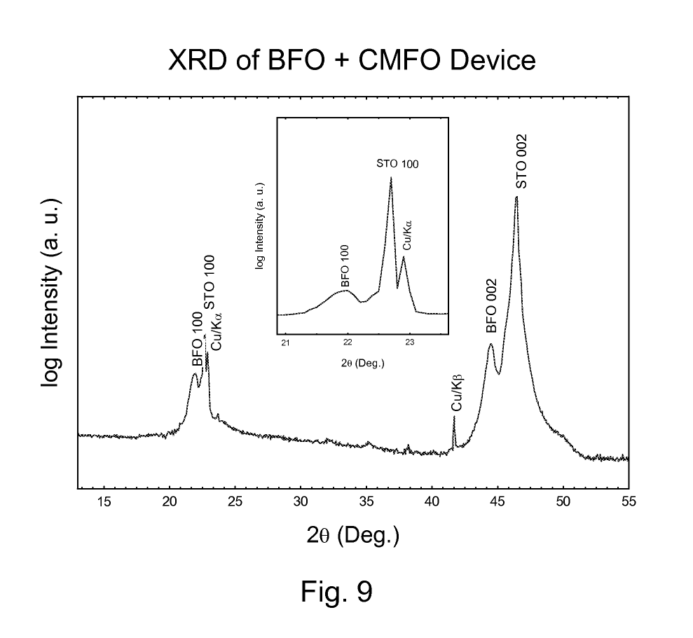

FIG. 9 shows the diffraction data from a BFO+CMFO film bilayer. The CMFO thin film was too thin (about 4 nm thickness) for any strong peaks to be evident; however, the BFO peaks are labeled on the graph. The BFO peak positions agreed closely with published literature for BFO films grown on STO (100) substrates. They also show relatively sharp BFO peaks which indicate fairly large crystals. This point shows a higher than typical degree of epitaxial growth on the substrate. High crystallinity is a favorable result for the BFO layer in a photovoltaic device.

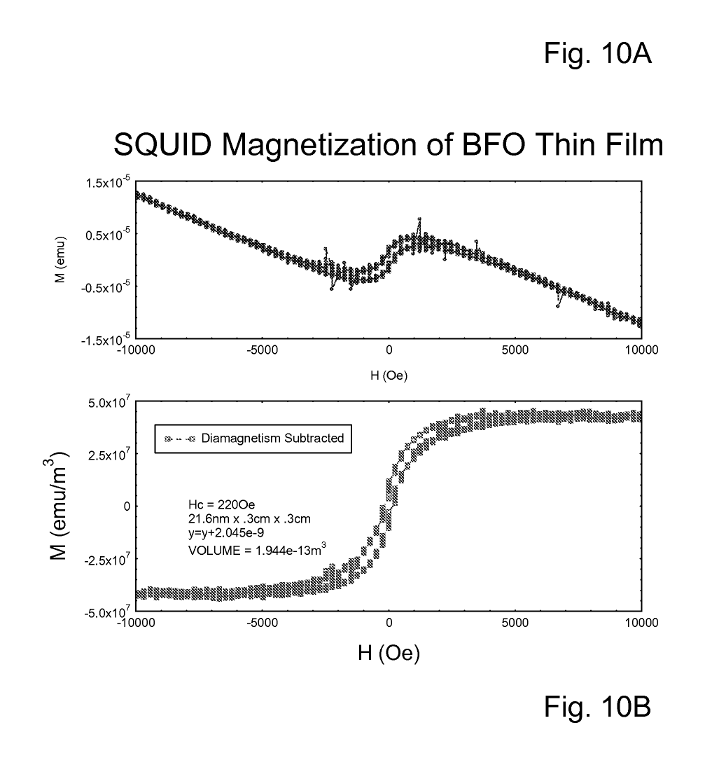

Room temperature magnetic characteristics were measured using a Quantum Design SQUID (superconducting quantum interference device) magnetometer. The results of a hysteresis run out to 1 tesla are shown in FIGS. 10A-10B. FIG. 10A shows the raw data obtained from the magnetometer. FIG. 10B shows the result after subtracting the diamagnetism of the STO substrate in order to accurately estimate the Mₛ, H_{c} and Mᵣ of the BFO film. The moment in FIG. 10B was also normalized to the estimated volume of the film (based on a thickness of 21.6 nm). The estimated volume was 1.944×10⁻¹³ m³. The obtained values for H_{c} and Mₛ agree closely with the literature values from previous magnetic measurements on BFO, which is known to be a soft antiferromagnet.

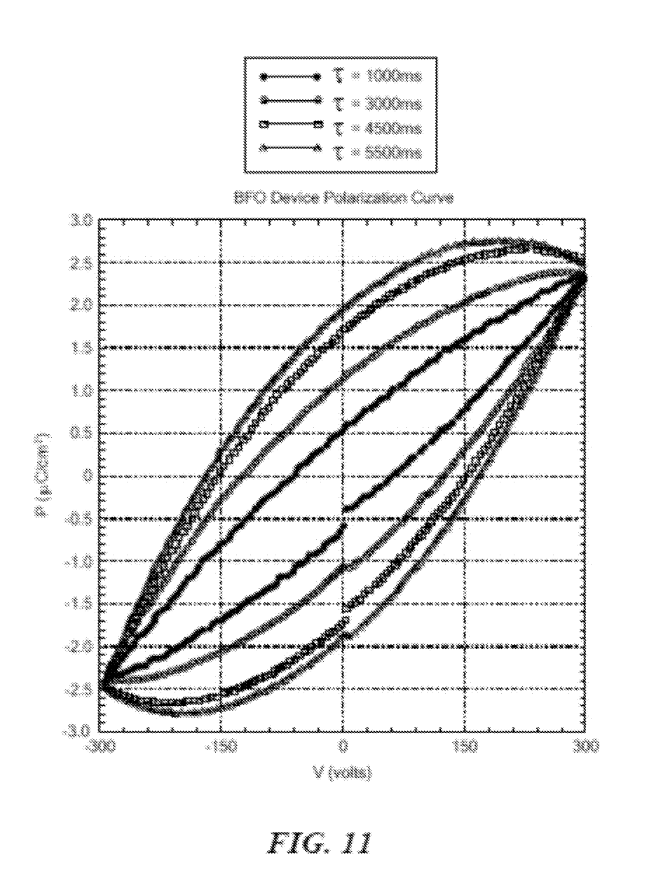

The sample polarizations were determined as a function of the applied poling voltage. P-V measurements were taken across an interdigital electrode (IDE) pattern, which was the same as used in the final device design (see Example 4). Polarization measurements were taken out to voltages of 500 V, though higher polarizations are possible with this electrode configuration on BFO, because dielectric breakdown is >1 kV. FIG. 11 shows PV loops for the BFO thin film grown on STO (100) across Ti/Au interdigital electrodes patterned on the surface via photolithography. The clear hysteresis in the PV loops indicates that there is an internal spontaneous electric field in the film. The changing shape with different time constants, τ, is typical for P-V loop measurements for ferroelectrics. Decreasing the time constant also decreases the remnant polarization in the specimen. Increasing the time constant increases the remnant polarization in the specimen, but also increases drift of the top of the loop to higher polarizations. Verification of the electric polarization in the BFO thin film confirmed the theoretical operation of the device produced in Example 4. The hysteresis loops lend proof to the presence of an electric field in the BFO.

### Example 4

### Photovolotaic Device Fabrication

A photovoltaic devices were fabricated containing essentially ferrite thin film bilayers grown on SrTiO₃ single crystals as substrates. The single crystals used for the substrates were (100) oriented after cleaving (purchased from MTI Corp.). This crystal orientation was chosen because when BFO is grown by PLD on these substrates the result is a ferroelectric domain pattern that serves to increase the internal electrical field of the film.

The initial BFO growth was carried out at 650° C. for 45 min at a laser pulse rate of 10 Hz. For device #1 this was the only ferrite layer deposited, so that it could act as a control in photovoltaic testing against the characteristics of the BFO+CMFO bilayer device. For device #2, however, a layer of CMFO was deposited in situ directly after the BFO layer at 650° C. and 10 Hz, but for only 5 min. After both layers were deposited, the substrate was cooled in a 100 mTorr O₂ atmosphere to 80° C. over 30 min. The cool down time can be extended to decrease the number of oxygen deficiencies in the system. A background working gas of O₂ was used at a pressure of 100 mTorr for the entire length of heating, cooling, and growth in the chamber. The oxygen environment was used to keep oxygen atoms in the lattice at stoichiometric values during the deposition.

CMFO nanoparticles were grown in situ on BFO film on STO (100) substrate by PLD at temperature of 650° C. for 45 min at a pulse rate of 10 Hz. After both layers were deposited the substrate was cooled in the 100 mTorr O₂ atmosphere to 80° C. over 30 min.

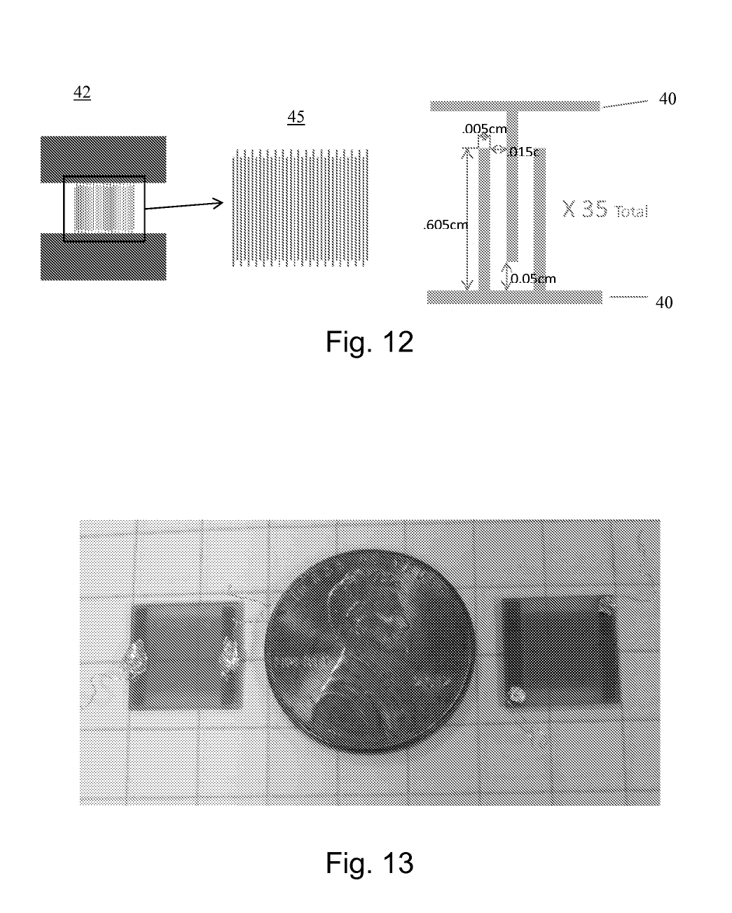

On top of the bilayer structure of device #2, or the BFO monolayer of device #1, interdigital Ti/Au electrodes were patterned on the surface by photolithography. Patterning was performed by first spinning Shipley 1827 photoresist on the surface and baking the layer on a hotplate at 100° C. for 1min. A photomask (see FIG. 12, structure 45) then was placed on top of the sample and the resist was exposed to UV light for 35 seconds. The photoresist was then developed by dipping it in 319 developer solution for 1 min followed by rinsing in DI H₂O for 3 minutes. The resulting electrode assembly (42) consists of two interdigital electrodes (40).

The spacing of the Ti/Au electrodes was 0.015 cm; the electrodes themselves were 0.005 cm in width. These dimensions can be varied to optimize the photocurrent and photovoltage. The Ti/Au electrodes were grown by magnetron sputtering of a titanium target with Au flakes placed on top of it. The sputtering was done with an RF power source with a power of SOW for 15 min. The working gas in the sputtering chamber was Ar held at 4-7 mTorr. Liftoff of the photoresist was then performed by dipping the sample into 1165 solution for 2 hrs at 80° C. Intermittent sonication in the 1165 solution was performed at 1 sec intervals to remove the remaining metal material between the electrodes.

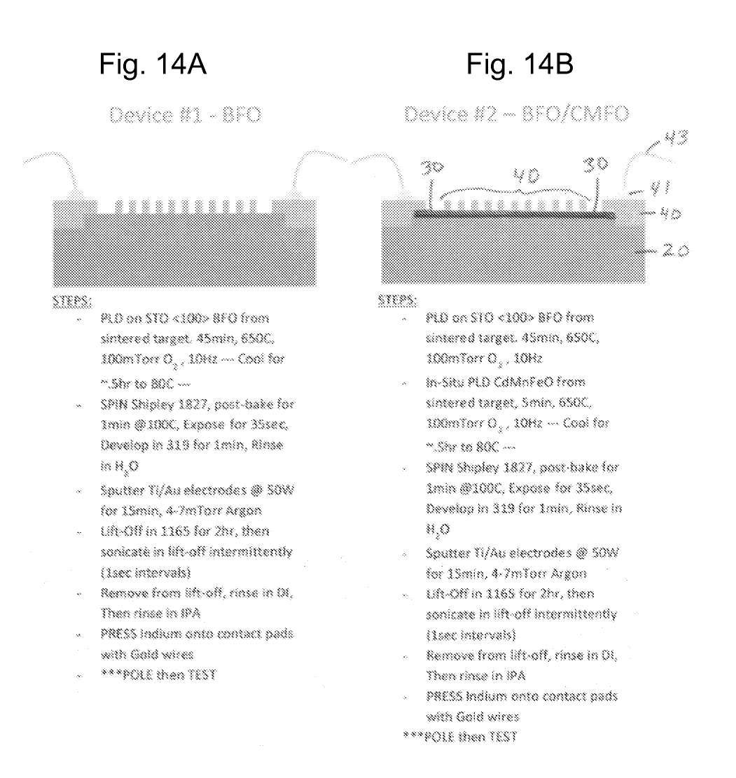

To make electrical contact to the contact pads of the electrodes, two gold wires were pressed into indium metal, which was then pressed onto the surface of the Ti/Au contact pad on the sample. A photo of the two devices (device #1 being the control with BFO only, and device #2 being the BFO+CMFO) is shown in FIG. 13. Device #2 appears darker than device #1, which shows a large difference in visible light absorption between BFO and CMFO. Not only does the whole device appear darker when the CMFO layer is present, but it does so with only a 2.5 nm thick coating of CMFO. FIGS. 14A and 14B show schematic cross-sections of the two devices and present a summary of the fabrication processes. Note that the device in FIG. 14B includes second layer 30 of CMFO nanoparticles which is not present in the device of FIG. 14A. The interdigital electrodes (40) are attached to a circuit through indium metal (41) pressed onto the contact pad area of the electrodes, and gold wires (43) attached to the indium.

### Example 5

### Photovolotaic Device Testing

The devices fabricated in Example 4 were tested using an Oriel solar illuminator. The illuminator was calibrated with a OEM Solar Power Meter. In all diagrams the power units of SUNS correlates to the metric 1 SUN=1000 W/m². All measurements were taken immediately after poling the device. A separate Stanford Research Systems high voltage power supply was used to pole the devices at 150V for 15 min.

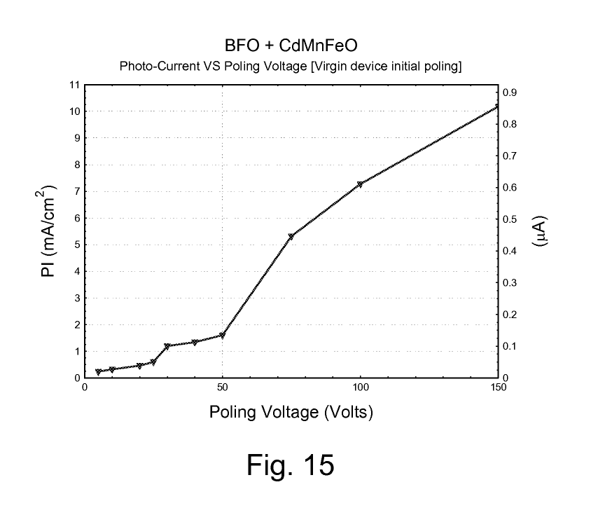

The curve for the virgin device polarization as a function of photocurrent shows how with higher poling voltage a higher photocurrent was achievable. This is because the higher the poling voltage, the larger the spontaneous field that exists in the sample when the voltage is removed. FIG. 15 presents variation of photocurrent density with poling voltage, showing PI up to 10 mA/cm² as poled at 160 volts.

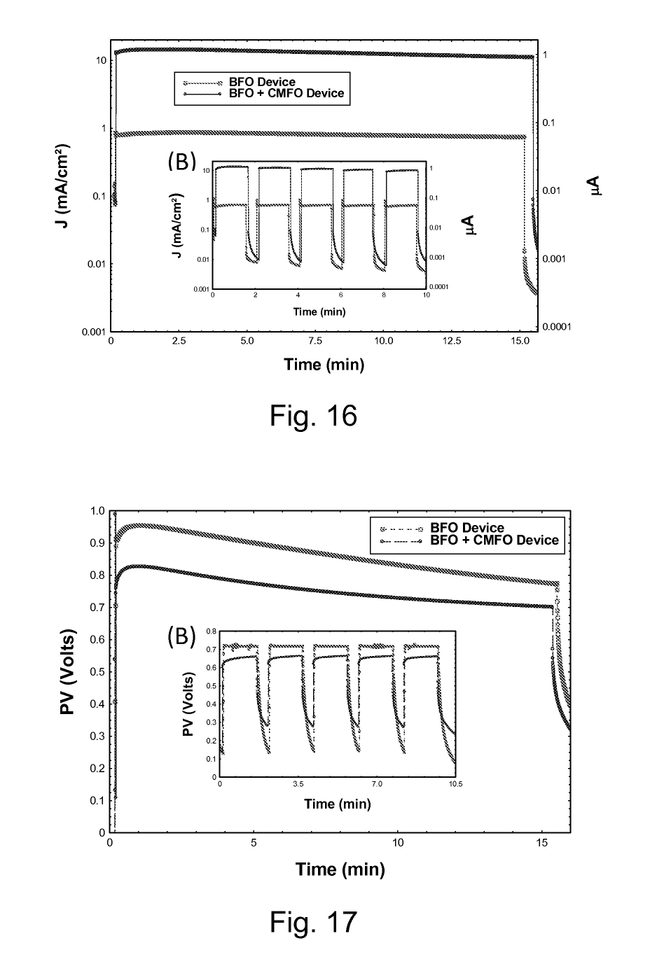

FIG. 16 shows the photocurrent measurements of both devices. The current measurements were taken using a Keithley 2182 Nanovoltmeter and collected using Labview. The current was measured by measuring the voltage drop across an in series 32.88 kOhm shunt resistor. Different resistor values were used without large changes in the photocurrent being measured. Future measurements of such devices might look into decreasing the resistance of this shunt resistor to increase the overall photocurrent measured.

The time dependence of the photocurrent was investigated. The data in FIG. 16 and FIG. 17 were taken immediately after poling the device. FIG. 17 shows how the photovoltage undergoes an initial increase after the illuminator is turned on. Initial spikes were always evident once the light was turned on, and as shown they are off the scale. After the initial spikes, the voltage increased for about a minute, but then its second derivative changed sign, and the photovoltage started to flatten out and then decrease. This trend has been explained previously in terms of the photovoltaic characteristics of BFO and is believed to be due to oxygen vacancies in the film. Controlling the oxygen vacancies is expected to reduce or eliminate the decrease in photovoltage with illumination time.

In analyzing the photovoltage curve in FIG. 17, it is apparent that the BFO device shows a higher photovoltage than that which incorporates the CMFO layer. This result is explained by the lower resistivity of CMFO and the larger carrier concentrations present in the BFO+CMFO device once the light is turned on. By increasing the distance between the electrodes, the effective electric field for charge carrier transport should increase, and by decreasing the spacing between the electrodes the photocurrent should increase and the open circuit voltage decrease. Thus, by generating samples with an array of electrode separations, the photocurrent and photovoltage can be optimized.

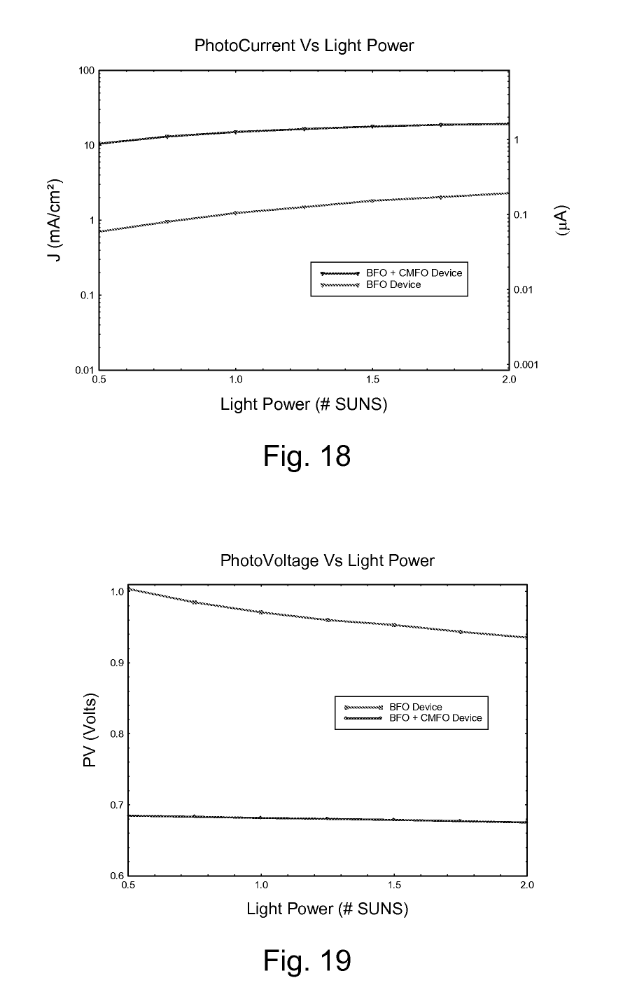

Also measured was the dependence of the photocurrent on the solar simulator's light power. Photovoltaics often are measured under multiple suns of power in order to maximize their photocurrent generation potential. Here, the power was varied from 0.5 SUNS to 2 SUNS, and the photocurrent was measured; the results are depicted in FIG. 18. An increasing photocurrent could be seen with the increasing illumination power. This is expected because as light intensity increases the probability of excitation also increases, which correlates with a larger number of photocarriers being carried by the spontaneous electric field in the system. FIG. 19 shows the dependence of open circuit photovoltage (V_{oc}) on light power. Unlike the photocurrent, the photovoltage decreased with increasing light power. This indirect relationship to light power is understandable because, even though current increases as seen in FIG. 18, the resistance to charge motion (mobility) stays the same. Therefore the rising current drives the voltage down because the intrinsic resistance does not change.

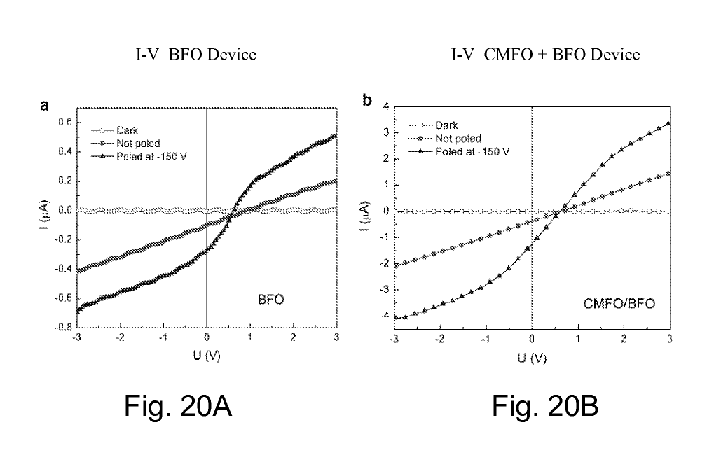

Lastly IV curves were measured to determine the overall electrical properties of the devices. The IV curves were obtained using a constant voltage applied to both contacts while measuring the current in a two point geometry, but using the interdigital planar electrodes. Two sweeps used for each device, one with the light on (closed symbols) and one with the light off (open circles). The results gave an offset IV curve for the light ON condition for both devices shown in FIGS. 20A and 20B. Due to the high resistance of the ferrite system, the light OFF condition shows a flat line close to zero for both devices. The light ON IV curves show a clear trend between −3V and 3V. Both devices showed an offset curve towards the 4th quadrant. This is expected, because with the light on there is a measureable current and a measureable voltage. It is important to note that before running this measurement the devices were polled in the positive direction, serving to offset the photovoltage to a positive value (compare diamonds (not poled) with triangles (after poling)). For the CMFO+BFO device the zero voltage biased photocurrent is an order of magnitude larger than that for the BFO device.

As used herein, “consisting essentially of” does not exclude materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

1. A photoferroelectric material comprising:
a crystalline substrate;
a first layer disposed on a surface of the substrate, the first layer comprising a ferrite material possessing an internal electrical polarization; and
a second layer disposed discontinuously on a surface of the first layer opposite the substrate, the second layer comprising a second ferrite material.

2. The photoferroelectric material of claim 1, wherein the second layer comprises a plurality of nanoparticles, nanocrystals, or quantum dots comprising the second ferrite material.

3. The photoferroelectric material of claim 1, wherein the second layer comprises a discontinuous thin film of the second ferrite material in the form of islands or patches.

4. The photoferroelectric material of claim 1, wherein the substrate comprises a material selected from the group consisting of SrTiO₃, MgO, BiFeO₃, and combinations thereof.

5. The photoferroelectric material of claim 1, wherein the first and/or second ferrite materials are independently selected from the group consisting of perovskites and spinels.

6. The photoferroelectric material of claim 1, wherein the first and/or second ferrite materials are independently selected from the group consisting of BiFeO₃, CdₓMn₍₁₋ₓ₎Fe₂O₄, [KNbO₃]₁₋ₓ[BaNi_{1/2}Nb_{1/2}O_{3-δ}]ₓ, (Na,K)NbO₃, LiNbO₃, KBiFe₂O₅, Pb[ZrₓTi₁₋ₓ]O₃, CoFe₂O₄, NiFe₂O₄, NiCr_{0.8}Fe_{1.2}O₄, and combinations thereof.

7. The photoferroelectric material of claim 6, wherein the first and/or second ferrite material is CdₓMn₍₁₋ₓ₎Fe₂O₄, and wherein x is from about 0.1 to about 1.0.

8. The photoferroelectric material of claim 6, wherein the first and/or second ferrite material is CdₓMn₍₁₋ₓ₎Fe₂O₄, wherein x is about 0.3.

9. The photoferroelectric material of claim 1, wherein the first and/or second ferrite materials each have a bandgap of less than about 2.5 eV.

10.-11. (canceled)

12. The photoferroelectric material of claim 1, wherein the first ferrite material is BiFeO₃, the second ferrite material is CdₓMn₍₁₋ₓ₎Fe₂O₄, and x is about 0.3.

13. The photoferroelectric material of claim 12, wherein the substrate is SrTiO₃ or DyScO₃.

14. The photoferroelectric material of claim 1, wherein the second ferrite material consists of a plurality of ferrimagnetic ferrite nanoparticles comprising said second ferrite material.

15. The photoferroelectric material of claim 1 that has a planar configuration.

16. The photoferroelectric material of claim 1, wherein the first layer has a thickness from about 10 nm to about 200 nm.

17. The photoferroelectric material of claim 1, wherein the second layer has a thickness from about 2 nm to about 10 nm.

18. The photoferroelectric material of claim 1, wherein the second layer comprises clusters of nanoparticles having a size ranging from about 20 nm×20 nm to about 50 nm×50 nm.

19. The photoferroelectric material of claim 1, wherein the second layer comprises nanoparticles of said second ferrite material, the nanoparticles having an average diameter from about 2 nm to about 10 nm.

20. The photoferroelectric material of claim 1, wherein the second layer covers from about 20% to about 80% of the surface area of the first layer.

21. A photovoltaic device comprising the photoferroelectric material of claim 1 and first and second metallic contacts disposed on and in electrical contact with the second layer of the material.

22. The photovoltaic device of claim 21, wherein the first and second metallic contacts are configured as first and second interdigital electrodes.

23. The photovoltaic device of claim 22, wherein the device has a planar configuration and the first and second interdigital electrodes are planar.

24. The photovoltaic device of claim 22, further comprising a transparent cover disposed above the first and second interdigital electrodes.

25. (canceled)

26. A solar array comprising a plurality of the photovoltaic devices of claim 16.

27. A method of making the photoferroelectric material of claim 1, the method comprising the steps of:
(a) providing a crystalline substrate, a first ferrite material, and a second ferrite material;
(b) depositing a thin film of the first ferrite material onto a surface of the substrate to form a first layer; and
(c) depositing a discontinuous thin film of the second ferrite material onto a surface of the first layer opposite the substrate to form a second layer.

28.-33. (canceled)

34. A method of making the photovoltaic device of claim 21, the method comprising the step of depositing first and second conductive electrodes onto a surface of the second layer of said photoferroelectric material opposite the first layer of said photoferroelectric material.

35. (canceled)
